(19) United States
(12) Patent Application Publication
(10) Pub. No.: US 2014/0295349 A1
(43) Pub. Date: Oct. 2, 2014

(54) BOTTOM ANTIREFLECTIVE MATERIALS AND COMPOSITIONS

(71) Applicants: Huirong YAO, Plainsboro, NJ (US); JoonYeon CHO, Bridgewater, NJ (US); Zachary BOGUSZ, Chatham, NJ (US); Salem K. MULLEN, Florham Park, NJ (US); Guanyang LIN, Whitehouse Station, NJ (US); Mark O. NEISSER, Whitehouse Station (NJ)

(72) Inventors: Huirong YAO, Plainsboro, NJ (US); JoonYeon CHO, Bridgewater, NJ (US); Zachary BOGUSZ, Chatham, NJ (US); Salem K. MULLEN, Florham Park, NJ (US); Guanyang LIN, Whitehouse Station, NJ (US); Mark O. NEISSER, Whitehouse Station (NJ)

(73) Assignee: AZ ELECTRONIC MATERIALS (LUXEMBOURG) S.A.R.L., SOMERVILLE, NJ (US)

(21) Appl. No.: 13/852,442

(22) Filed: Mar. 28, 2013

(51) Int. Cl. G03F 7/09; G03F 7/20

(52) U.S. Cl. CPC G03F 7/091; G03F 7/20
USPC 430/271.1; 525/418; 528/367; 528/211; 528/296; 524/600; 524/612; 524/539; 524/500; 524/236; 524/157; 524/158; 524/159; 430/325

(57) ABSTRACT

The present invention relates to novel antireflective coating compositions and their use in image processing. The compositions self-segregate to form hydrophobic surfaces of the novel antireflective coating compositions, the composition being situated between a reflective substrate and a photoresist coating. Such compositions are particularly useful in the fabrication of semiconductor devices by photolithographic techniques. The present invention also related to self-segregating polymers useful in image processing and processes of their use.

### FIELD OF INVENTION

The present invention relates to novel antireflective coating compositions and their use in image processing. The compositions self-segregate to form hydrophobic surfaces of the novel antireflective coating compositions, the composition being situated between a reflective substrate and a photoresist coating. Such compositions are particularly useful in the fabrication of semiconductor devices by photolithographic techniques. The present invention also related to self-segregating polymers useful in image processing and processes of their use.

### BACKGROUND

Photoresist compositions are used in microlithography processes for making miniaturized electronic components such as in the fabrication of computer chips and integrated circuits. Generally, in these processes, a thin coating of film of a photoresist composition is first applied to a substrate material, such as silicon wafers used for making integrated circuits. The coated substrate is then baked to evaporate much of the solvent in the photoresist composition and to fix the coating onto the substrate. The dried coated surface of the substrate is next subjected to an image-wise exposure to radiation.

This radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is treated with a developer solution to dissolve and remove either the radiation-exposed or the unexposed areas of the photoresist.

The trend towards the miniaturization of semiconductor devices has led to the use of new photoresists that are sensitive to lower and lower wavelengths of radiation and has also led to the use of sophisticated multilevel systems to overcome difficulties associated with such miniaturization.

The use of highly absorbing antireflective coatings in photolithography is one approach to diminish the problems that result from back reflection of light from highly reflective substrates. Two major disadvantages of back reflectivity are thin film interference effects and reflective notching. Thin film interference, or standing waves, result in changes in critical line width dimensions caused by variations in the total light intensity in the photoresist film as the thickness of the photoresist changes. Reflective notching becomes severe as the photoresist is patterned over substrates containing topographical features, which scatter light through the photoresist film, leading to line width variations, and in the extreme case, forming regions with complete photoresist loss.

In cases where further reduction or elimination of line width variation is required, the use of bottom antireflective coating provides the best solution for the elimination of reflectivity. The bottom antireflective coating is applied to the substrate prior to coating with the photoresist and prior to exposure. The photoresist is exposed imagewise and developed. The antireflective coating in the exposed area is then etched, typically in gaseous plasma, and the photoresist pattern is thus transferred to the substrate. The etch rate of the antireflective film should be relatively high in comparison to the photoresist so that the antireflective film is etched without excessive loss of the photoresist film during the etch process. Antireflective coatings must also possess the correct absorption and refractive index at the wavelength of exposure to achieve the desired lithographic properties.

It is necessary to have a bottom antireflective coating that functions well at exposures less than 300 nm. Such antireflective coatings need to have high etch rates and be sufficiently absorbing with the correct refractive index to act as antireflective coatings. As finer and finer photoresist structures are created, such as through immersion lithography and extreme ultraviolet (EUV) exposures, a variety of problems result, such as image collapse, footing, line edge roughness and other poor pattern profile characteristics.

The novel antireflective compositions of the present invention comprise novel hydrophobic polyester polymers based on unique chemical structures which have surprisingly been found to phase separate during the drying step and come to the surface of the composition layer. Adding these novel polymers to bottom antireflective compositions enable a good image transfer from the photoresist to the substrate, lower attack of the antireflective coating by the developer, improved collapse margin, improved pattern profile, and improved line edge roughness, particularly during immersion lithography or EUV exposure.

### DESCRIPTION OF THE FIGURES

FIG. 1 shows examples of dianhydrides useful in the preparation of the novel polymers of the current disclosure.

FIGS. 2A and 2B show example of polymer intermediates useful in the preparation of the current disclosure.

FIGS. 3 A and 3B show novel polymers disclosed and claimed herein.

FIG. 4 shows examples of crosslinking polymer materials useful in the novel compositions of the current disclosure.

FIGS. 5 A and 5B shows examples of additional crosslinkable polymer materials useful in the novel compositions of the current disclosure.

### SUMMARY OF THE DISCLOSURE

The present invention relates to novel antireflective coating compositions and their use in image processing as well as novel polymers that are a component of such antireflective compositions.

In a first embodiment, disclosed and claimed herein are antireflective coating compositions for a photoresist layer comprising a first novel polymer and an acid generator, where the first polymer comprises at least one unit of structure 1,

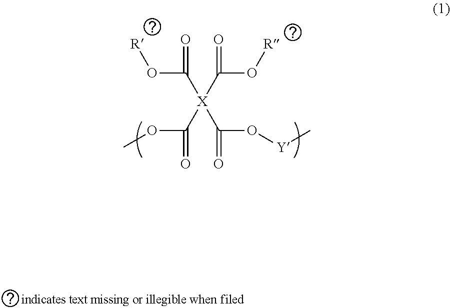

wherein, X is a linking moiety selected from a nonaromatic linking group selected from C₁-C₂₀ substituted or unsubstituted aliphatic, heteroaliphatic, cycloaliphatic or heterocycloaliphatic linking groups, an aromatic linking group and mixtures thereof, wherein R′ is a group of structure (2), or (3) or a mixture thereof,

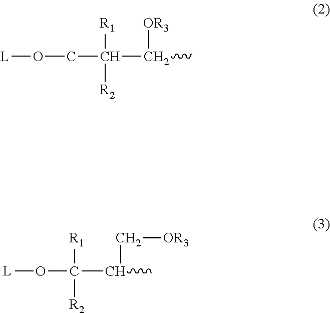

wherein R₁ and R₂ are independently selected from H and C₁-C₄ alkyl, R₃ is H or ˜˜˜CH₂—Z, wherein Z is an acid crosslinkable aminoplast and L is a C₁-C₂₀ substituted or unsubstituted, branched or unbranched aliphatic, aromatic, or aralkyl linking group which is fully or partially substituted with fluorine groups, R″ is selected from a group consisting of C₁-C₂₀ substituted or unsubstituted, branched or unbranched aliphatic, aromatic, or aralkyl linking group, structure (2) and (3) where R₃ is selected from a group consisting of H, C₁-C₂₀ substituted or unsubstituted, branched or unbranched aliphatic, substituted or unsubstituted, branched or unbranched aromatic, substituted or unsubstituted, branched or unbranched alkylene aryl, substituted or unsubstituted, branched or unbranched aralkyl linking group, and ˜˜˜CH₂—Z, wherein Z is an acid crosslinkable aminoplast, and mixtures thereof, and Y′ is independently a (C₁-C₂₀) substituted or unsubstituted, branched or unbranched aliphatic, substituted or unsubstituted, branched or unbranched aromatic, or substituted or unsubstituted, branched or unbranched aralkyl linking groups.

In a further embodiment, disclosed and claimed herein is a process for forming an image comprising, coating and baking a substrate with any of the antireflective coating composition of the above embodiments; coating and drying a photoresist film on top of the antireflective coating; imagewise exposing the photoresist; developing an image in the photoresist; and optionally baking the substrate after the exposing step.

In still a further embodiment, disclosed and claimed herein is the process of the above embodiment wherein the photoresist is imagewise exposed at wavelengths between 13 nm to 250 nm, the photoresist comprises a polymer and a photoactive compound, and the antireflective coating is baked at temperatures greater than 90° C.

In still a further embodiment, disclosed and claimed herein are articles comprising a substrate with a layer of any of the antireflective coating compositions of the above embodiments and thereon a coating of photoresist comprising a polymer and a photoactive compound.

### DETAILED DESCRIPTION

As used herein, the conjunction “and” is intended to be inclusive and the conjunction “or” is not intended to be exclusive unless otherwise indicated. For example, the phrase “or, alternatively” is intended to be exclusive.

As used herein, the term “and/or” refers to any combination of the foregoing elements including using a single element.

Aryl groups contain 6 to 24 carbon atoms including phenyl, tolyl, xylyl, naphthyl, anthracyl, biphenyls, bis-phenyls, tris-phenyls and the like. These aryl groups may further be substituted with any of the appropriate substituents e.g. alkyl, alkoxy, acyl or aryl groups mentioned hereinabove. Similarly, appropriate polyvalent aryl groups as desired may be used in this invention. Representative examples of divalent aryl groups include phenylenes, xylylenes, naphthylenes, biphenylenes, and the like.

Aralkyl means aryl groups with attached substituents. The substituents may be any such as alkyl, alkoxy, acyl, etc. Examples of monovalent aralkyl having 7 to 24 carbon atoms include phenylmethyl, phenylethyl, diphenylmethyl, 1,1- or 1,2-diphenylethyl, 1,1-, 1,2-, 2,2-, or 1,3-diphenylpropyl, and the like. Appropriate combinations of substituted aralkyl groups as described herein having desirable valence may be used as a polyvalent aralkyl group.

As used herein the term “alkyl” refers to straight, or cyclic chain alkyl substituents as well as any of their branched isomers.

As used herein the term “alkylene” refers to straight or cyclic chain alkylene substituents as well as any of their branched isomers.

Furthermore, and as used herein, the term “substituted” is contemplated to include all permissible substituents of organic compounds. In a broad aspect, the permissible substituents include acyclic and cyclic, branched and unbranched, carbocyclic and heterocyclic, aromatic and non-aromatic substituents of organic compounds. Illustrative substituents include, for example, those described hereinabove. The permissible substituents can be one or more and the same or different for appropriate organic compounds. For purposes of this invention, the heteroatoms such as nitrogen may have hydrogen substituents and/or any permissible substituents of organic compounds described herein which satisfy the valencies of the heteroatoms. This invention is not intended to be limited in any manner by the permissible substituents of organic compounds.

Disclosed and claimed herein are novel polymers of the following general structure (1):

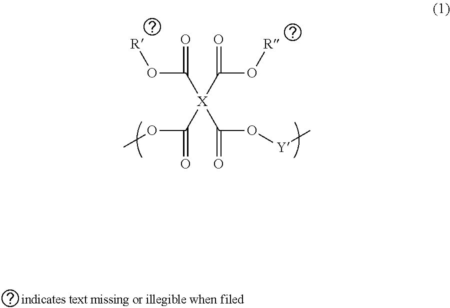

wherein, X is a linking moiety selected from an aliphatic linking group selected from C₁-C₂₀ substituted or unsubstituted aliphatic, C₁-C₂₀ substituted or unsubstituted heteroaliphatic, C₁-C₂₀ substituted or unsubstituted cycloaliphatic or C₁-C₂₀ substituted or unsubstituted heterocycloaliphatic linking groups, an aromatic linking group and mixtures thereof, that connect the four carboxyl groups in structure (1). Examples of suitable X moieties are butyl, propyl, cyclopentyl, furanyl, cyclohexyl, tetrahydrofuranyl, norbornenyl, phenyl, naphthyl, diphenylether, benzophenone, biphenyl and the like.

The R′ group of general structure (1) is structure (2), or (3) below or a mixture thereof:

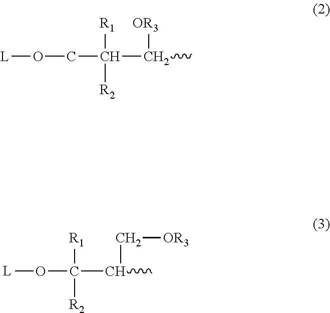

where R₁ and R₂ are independently selected from H and C₁-C₄ alkyl. R₃ is pendent group ˜˜˜CH₂—Z wherein Z is an acid crosslinkable aminoplast.

Suitable aminoplasts are selected from monomeric or oligomeric melamines, guanamines, methylols, monomeric or oligomeric glycolurils, hydroxy alkyl amides, N-substituted cyanuric acids, triazines, epoxy and epoxy amine resins, blocked isocyanates, and divinyl monomers. The aminoplast can be substituted by two or more alkoxy groups and can be based on aminoplasts such as, for example, glycoluril-aldehyde resins, melamine-aldehyde resins, benzoguanamine-aldehyde resins, and urea-aldehyde resins. Examples of the aldehyde include formaldehyde, acetaldehyde, etc. In some instances, three or four alkoxy groups are useful. Monomeric, alkylated glycoluril-formaldehyde resins are examples. One example is tetra (methoxymethyl) glycolurils. Further examples suitable for the current disclosure can be found in US 2010/0009297 A1 to Yao et al, incorporated as a reference herein for the aminoplasts described therein.

L is a C₁-C₂₀ substituted or unsubstituted, branched or unbranched aliphatic, substituted or unsubstituted, branched or unbranched aromatic, or substituted or unsubstituted, branched or unbranched aralkyl linking group which is fully or partially substituted with fluorine groups, for example, 1,1,2,2-tetrafluoroethyl, 2,2,3,3-tetrafluoropropyl, 2,2,3,3,4,4,5,5,-octofluoropentyl, or glycidyl 2,2,3,3,4,4,5,5,6,6,7,7,8,8,9,9-hexadecafluorononyl ether groups.

R″ is selected from a group consisting of C₁-C₂₀ substituted or unsubstituted, branched or unbranched aliphatic, C₁-C₂₀ substituted or unsubstituted, branched or unbranched aromatic, C₁-C₂₀ substituted or unsubstituted, branched or unbranched aralkyl group, structure (2) and structure (3), where R₁, R₂ and L are as described above and R₃ is selected from a group consisting of H, C₁-C₂₀ substituted or unsubstituted, branched or unbranched aliphatic, substituted or unsubstituted, branched or unbranched aromatic, substituted or unsubstituted, branched or unbranched alkylene aryl, substituted or unsubstituted, branched or unbranched aralkyl group, and ˜˜˜CH₂—Z, wherein Z is an acid crosslinkable aminoplast, and mixtures thereof. The substituents may be hydroxyl, ethers, acetyl, etc. R″ groups can be attached to the inventive polymer by reaction of a carboxylic acid group remaining from the dianhydride reactions with an epoxy group such as, for example, aliphatic glycidyl ethers, aromatic glycidyl ethers, halogenated glycidyl ethers, including methyl glycidyl ether, ethyl glycidyl ether, butyl glycidyl ether, decyl glycidyl ether, dodecyl glycidyl ether, allyl glycidyl ether, glycidyl 1,1,2,2-tetrafluoroethyl ether, glycidyl 2,2,3,3-tetrafluoropropyl ether, glycidyl 2,2,3,3,4,4,5,5-octafluoropentyl ether, styrene oxide, propylene oxide and other substituted or unsubstituted, branched or unbranched epoxy materials. These reactions result in a hydroxy substituent on the ester group. Other materials may also be used which can add to a carboxylic acid such as, for example, oxetanes, Michael addition across an olefin, substitution reactions, and the like. Then pendent hydroxy group resulting from these reactions may further be reacted with other functional groups, such as, for example, aminoplasts or other materials to give desired functionality.

Y′ is independently a (C₁-C₂₀) substituted or unsubstituted, branched or unbranched aliphatic, aromatic, or aralkyl linking group. Examples of Y′ groups suitable for the current disclosure can be found in US 2011/0104613 A1 to Yao et al, incorporated as a reference herein for the Y′ groups described therein.

In a first embodiment of the compositions, disclosed and claimed herein are antireflective coating compositions for a photoresist layer comprising the novel first polymer described above and an acid generator. The acid generator may be a thermal acid generator or photoacid generator.

In a further embodiment, disclosed and claimed herein are coating compositions of the above first embodiment further comprising a second polymer comprising a structural unit derived from an aminoplast and a structural unit derived from a diol, triol, dithiol, trithiol, polyols, diacid, triacid, polyacids, diimide, diamide, imide-amide, or mixture thereof, where the diol, dithiol, triol, trithiol, diacid, triacid, diimide, diamide, or imide-amide optionally contain one or more nitrogen and/or sulfur atoms or contain one or more alkene groups as described in U.S. Pat. No. 7,691,556 B2, U.S. Pat. No. 8,329,387 B2, and US 2012/0202155 A1. Additional polymer/oligomer with crosslinking groups such as hydroxyl, carboxylic acid, or amino groups can be added in the composition to enhance the lithography performances as described in U.S. Pat. No. 7,638,262 B2, US 2011/0200938 A1. The amount of second polymer in the solid composition is 30-99.9 wt %, or 50-90 wt %. The amount of additional polymer in solid composition is 5-50 wt %, or 10-35 wt %. The novel first polymer is the graded component and the amount in the composition is 0.1-20 wt %, or 0.5-10 wt %. The total solid content in the formulation ranges from 0.1-30 wt %, or 0.5-15 wt %, to give the desired the film thickness of the coating.

In a further embodiment, disclosed and claimed herein are coating composition of the above embodiments, wherein the aminoplasts are selected from monomeric or oligomeric melamines, guanamines, methylols, monomeric or oligomeric glycolurils, hydroxy alkyl amides, epoxy and epoxy amine resins, blocked isocyanates, and divinyl monomers, wherein the acid generator may be a thermal acid generator selected from alkyl ammonium salts of organic acids, ammonium salts of organic sulfonic acids, phenolic sulfonate esters, nitrobenzyl tosylates, and metal-free iodonium and sulfonium salts and wherein the first polymer is capable of segregating from any other materials present toward the surface of the coating when coated and substantially dried, the acid generator may be a photoacid generator including onium salt compounds, sulfone imide compounds, halogen-containing compounds, sulfone compounds, ester sulfonate compounds, quinone diazide compounds, and diazomethane compounds, specific examples of which are indicated below or the acid generator may be a combination of both a thermal acid generator and a photoacid generator.

In a further embodiment, disclosed and claimed herein are coating compositions of the above embodiments wherein the first novel polymer is of structure 4,

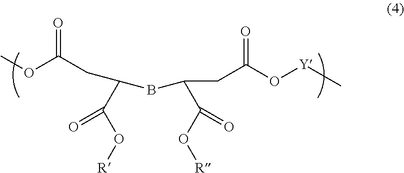

wherein, B is a single bond or C₁-C₆ nonaromatic aliphatic group, R′ is the group structure (2), or (3) wherein R₁ and R₂ are independently selected from H and C₁-C₄ alkyl, R₃ is H or ˜˜˜CH₂—Z, wherein Z is an acid crosslinkable aminoplast and L is a C₁-C₂₀ substituted or unsubstituted, branched or unbranched aliphatic, C₁-C₂₀ substituted or unsubstituted, branched or unbranched aromatic, or C₁-C₂₀ substituted or unsubstituted, branched or unbranched aralkyl group which is fully or partially substituted with fluorine groups, R″ is selected from a group consisting of C₁-C₂₀ substituted or unsubstituted, branched or unbranched aliphatic, C₁-C₂₀ substituted or unsubstituted, branched or unbranched aromatic, C₁-C₂₀ substituted or unsubstituted, branched or unbranched aralkyl group, structure (2) and structure (3) where R₁, R₂ and L are as described previously and R₃ is selected from a group consisting of H, C₁-C₂₀ substituted or unsubstituted, branched or unbranched aliphatic, C₁-C₂₀ substituted or unsubstituted, branched or unbranched aromatic, C₁-C₂₀ substituted or unsubstituted, branched or unbranched alkylene aryl linking group, C₁-C₂₀ substituted or unsubstituted, branched or unbranched aralkyl linking group, and ˜˜˜CH₂—Z, wherein Z is an acid crosslinkable aminoplast, and Y′ is independently a (C₁-C₂₀) substituted or unsubstituted, branched or unbranched aliphatic, (C₁-C₂₀) substituted or unsubstituted, branched or unbranched aromatic, or (C₁-C₂₀) substituted or unsubstituted, branched or unbranched aralkyl linking group.

In a further embodiment, disclosed and claimed herein are polymers with structures 1 and 4 of the above embodiments.

The novel polymers of the current disclosure are typically obtained by reacting at least one class of dianhydride with at least one class of diol to result in a polyester containing two free carboxylic acid groups in its basic unit. The carboxylic acid groups of the resulting polymer may be further reacted with one or more epoxy groups, which result in at least one free hydroxy group. The resulting hydroxy groups can be reacted with acid sensitive crosslinking aminoplast groups to give crosslinking functionality to the polymer, or with other groups to cap the hydroxyl group.

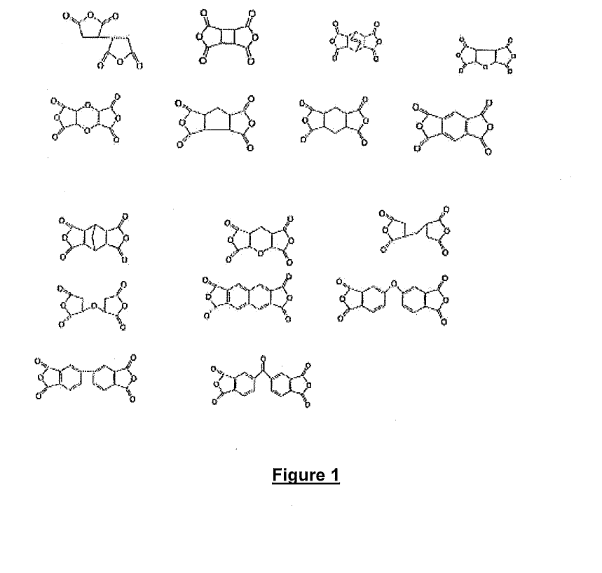

Examples for anhydrides suitable for reaction to provide novel polymers of the current disclosure are shown in FIG. 1. Diols used to provide the novel polymer are those well known in the art that react with anhydrides to prepare polyester.

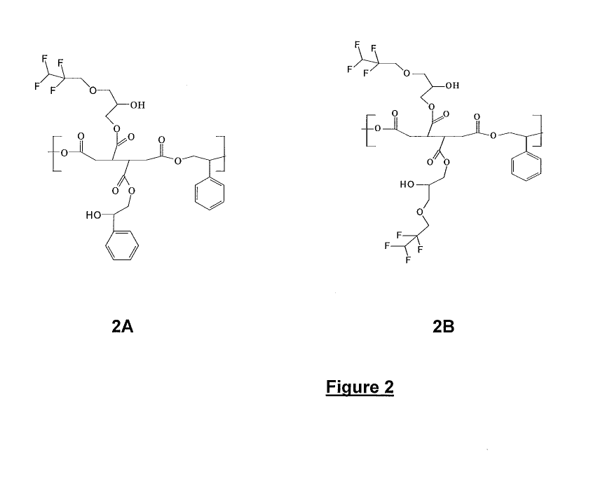

The reaction product of the dianhydride and the diol contains two free carboxylic acid acids. One or more of these are reacted with epoxy moieties that contain the desired functionality, such as structures (2) and (3) above. An example is shown in FIG. 2A which shows the product of the polymerization reaction of 1 part butane dicarboxylic acid anhydride and 1 part styrene glycol, to form the polyester, followed by reaction of 1 part 2,2,3,3-tetrafluoropropyl glycidyl ether and 1 part styrene oxide with the free acid groups from the polymerization reaction. FIG. 2B shows an example where 2 parts of 2,2,3,3-tetrafluoropropyl glycidyl ether is used.

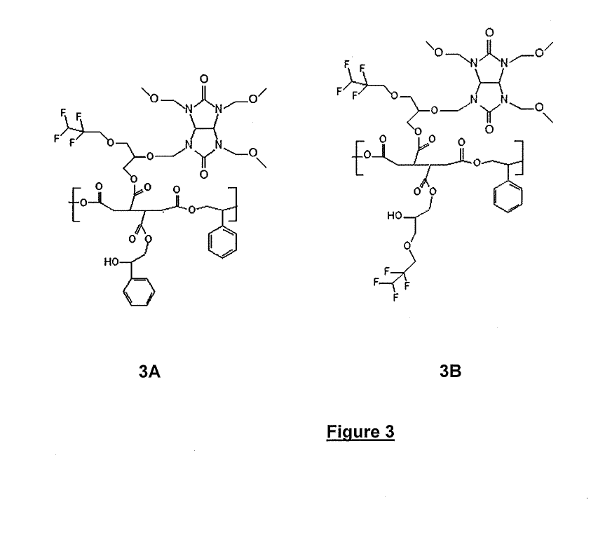

As shown in FIGS. 2A and 2B, hydroxy groups result from the reaction of the epoxy and carboxylic acid groups. At least one of these hydroxy groups is reacted with at least one aminoplast crosslinking groups. Examples of the resultant novel polymers of the current disclosure are shown in FIGS. 3A and 3B.

Also disclosed and described herein are antireflective coating compositions for a photoresist layer comprising a first polymer of structure (1) described above and an acid generator. The acid generator may be at least one thermal acid generator that, upon heating, generates an acid which can react with the acid sensitive aminoplast pendent to the novel first polymer causing crosslinking of the polymer to itself and other components of the composition, such as a second crosslinkable polymer, oligomer, or monomer. Thermal acid generators suitable for the current disclosure include, for example, sulfonic acid precursors. Other examples of thermal acid generators include for example, metal-free iodonium and sulfonium salts, nitrobenzyl tosylates, such as 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chloro benzenesulfonate, 2-trifluoromethyl-6-nitrobenzyl-4-nitro benzenesulfonate; phenolic sulfonate esters such as phenyl, 4-methoxybenzenesulfonate; alkyl ammonium salts of organic acids, such as triethylammonium salt of 10-camphorsulfonic acid. Iodonium salts can be exemplified by iodonium fluorosulfonates, iodonium tris(fluorosulfonyl)methide, iodonium bis(fluorosulfonyl)methide, iodonium bis(fluorosulfonyl)imide, iodonium quaternary ammonium fluorosulfonate, iodonium quaternary ammonium tris(fluorosulfonyl) methide, and iodonium quaternary ammonium bis (fluorosulfonyl)imide. A variety of aromatic (anthracene, naphthalene or benzene derivatives) sulfonic acid amine salts can be employed as the TAG, including those disclosed in U.S. Pat. No. 3,474,054, U.S. Pat. No. 4,200,729, U.S. Pat. No. 4,251,665 and U.S. Pat. No. 5,187,019. The acid generator in the present composition can vary from 0.1 weight % to about 10 weight % relative to the solid portion of the composition.

The acid generator may further comprise at least one photo acid generator that, upon exposure to actinic radiation, generates an acid which can react with the acid sensitive aminoplast pendent to the novel first polymer causing crosslinking of the polymer to itself and other components of the composition, such as a second crosslinkable polymer, oligomer, or monomer. Examples of onium salt compounds include sulfonium salts, iodonium salts, phosphonium salts, diazonium salts and pyridinium salts.

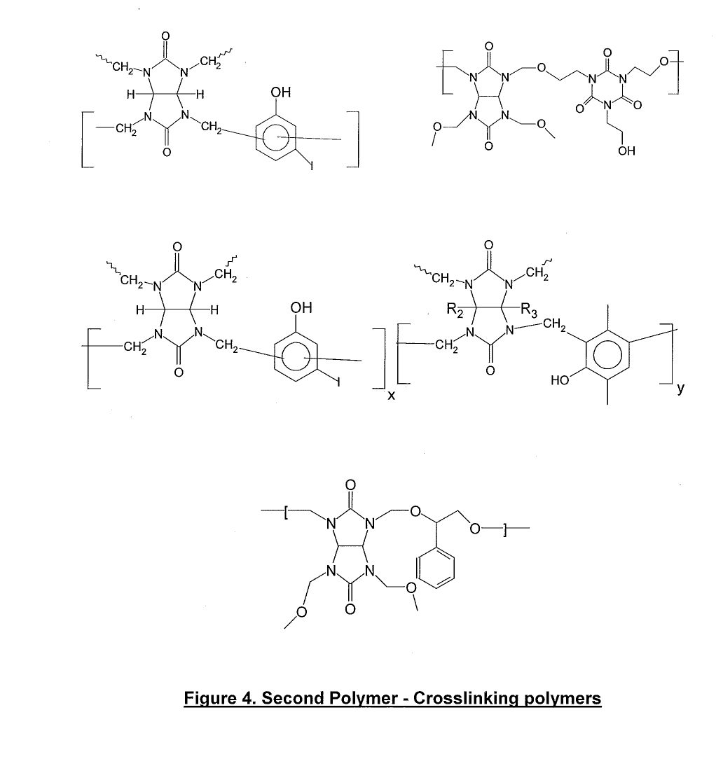

A second polymer which is free of fluorinated groups can be included in the antireflective composition comprising the first novel polymer and the acid generator. For example, a polymer having a structural unit derived from an aminoplast and a structural unit derived from a diol, triol, dithiol, trithiol, polyols, diacid, triacid, polyacids, diimide, diamide, imide-amide, or a mixture thereof, where the diol, dithiol, triol, trithiol, diacid, triacid, diimide, diamide, or imide-amide optionally contain one or more nitrogen and/or sulfur atoms or contain one or more alkene groups. The aminoplasts useful in the second polymer include, for example, monomeric or oligomeric melamines, guanamines, methylols, monomeric or oligomeric glycolurils, N-substituted cyanuric acids, triazines, hydroxy alkyl amides, epoxy and epoxy amine resins, blocked isocyanates, and divinyl monomers. When incorporated into the novel compositions of the current disclosure, the aminoplasts of the second polymer crosslink with the novel polymer during either thermal processing or photo-processing or both to create a hardened coating. Second polymers of the current disclosure can be found in U.S. Pat. No. 7,691,556 B2, U.S. Pat. No. 8,329,387 B2, and US 2012/0202155 A1, incorporated herein by reference for the oligomeric and polymeric materials described therein. Examples of suitable second polymers are shown in FIG. 4.

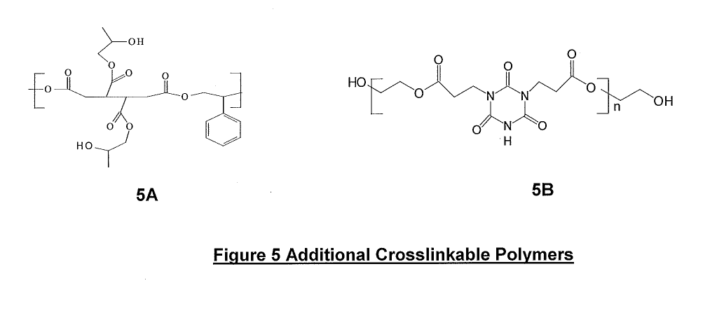

Additional third polymer/oligomer with crosslinkable groups such as hydroxyl, carboxylic acid, or amino groups can be added to the inventive compositions to enhance the lithography performances. When incorporated into the novel compositions of the current disclosure, the crosslinking groups of the additional polymer/oligomer crosslink with the novel polymer and/or the second polymer during either thermal processing or photo-processing or both to create a hardened coating. Examples of additional polymers include structures 1 through 4 above absent of fluorination and/or aminoplast functional groups. Other suitable examples of additional polymers of the current disclosure can be found in U.S. Pat. No. 7,638,262 B2, and US 2011/0200938 A1, incorporated herein by reference for the oligomeric and polymeric materials described therein. Additional polymers are shown in FIGS. 5A and 5B. These polymers contain hydroxy crosslinking functionalities which crosslink with first polymer when acid is generated is the curing process. The additional third polymer crosslinks with novel polymer and/or the second polymer during processing. It should be stated that any polymer may be used in the current disclosure if the polymer contains functionalities which will crosslink with the aminoplast of the novel polymer and/or second polymer in the presence of a catalytically amount of thermally or photochemically generated acid. The amount of second polymer in the solid composition is 30-99.9 wt %, or 50-90 wt %. The amount of additional polymer in solid composition is 5-50 wt %, or 10-35 wt %. The first novel polymer is the graded component and the amount in the composition is 0.1-20 wt %, or 0.5-10 wt %. The total solid content in the formulation ranges from 0.1-30 wt %, or 0.5-15 wt %, to give the desired the film thickness of the coating.

In other embodiments the novel first polymer may be included in other known bottom antireflecting compositions. It has surprisingly been found that the first polymer is self-segregating from the remainder of the coating composition during the coating and drying process, so that the surface contains a higher proportion of the first polymer than the remaining bulk of the composition. As such, its presence in other antireflective compositions will also allow self-segregating in those compositions resulting in similar surface characteristics.

The components of the composition form a homogeneous solution in the coating solvent. Examples of suitable solvents for the current disclosure include ethers, esters, etheresters, ketones and ketoneesters and, more specifically, ethylene glycol monoalkyl ethers, diethylene glycol dialkyl ethers, propylene glycol monoalkyl ethers, propylene glycol dialkyl ethers, acetate esters, hydroxyacetate esters, lactate esters, ethylene glycol monoalkylether acetates, propylene glycol monoalkylether acetates, alkoxyacetate esters, (non-)cyclic ketones, acetoacetate esters, pyruvate esters and propionate esters. The aforementioned solvents may be used independently or as a mixture of two or more types. High boiling point solvent such as such as benzylethyl ether, dihexyl ether, diethylene glycol monomethyl ether, diethylene glycol monoethyl ether, acetonylacetone, isoholon, caproic acid, capric acid, 1-octanol, 1-nonanol, benzyl alcohol, benzyl acetate, ethyl benzoate, diethyl oxalate, diethyl maleate, γ-butyrolactone, gamma-valerolactone (GVL), ethylene carbonate, propylene carbonate and phenylcellosolve acetate may be added to the aforementioned solvent.

The present composition can optionally comprise additional materials typically found in antireflective coating compositions such as, for example, monomeric dyes, lower alcohols, surface leveling agents, adhesion promoters, antifoaming agents, etc, provided that the performance is not negatively impacted.

The substrates over which the antireflective coatings are formed can be any of those typically used in the semiconductor industry. Suitable substrates include, without limitation, silicon, silicon substrate coated with a metal surface, copper coated silicon wafer, copper, substrate coated with antireflective coating, aluminum, polymeric resins, silicon dioxide, metals, doped silicon dioxide, silicon nitride, silicon oxide nitride, titanium nitride, tantalum, tungsten, copper, polysilicon, ceramics, aluminum/copper mixtures; gallium arsenide and other such Group IIIN compounds, and the like. The substrate may comprise any number of layers made from the materials described above.

The coating composition can be coated on the substrate using techniques well known to those skilled in the art, such as dipping, spin coating or spraying. The film thickness of the anti-reflective coating ranges from about 0.01 micron to about 1 micron. The coating can be heated on a hot plate or convection oven or other well-known heating methods to remove any residual solvent.

The novel first polymer self-segregates from the composition during spin-coating and drying process so that the surface of the dried coating contains an appropriate higher proportion of fluorinated materials compared to the remaining bulk of the coating to cause self-segregation. The contact angle (CA) to water can be measured for the layers formed from compositions containing various amounts of the first novel polymer (1-25 wt % in total solid). Generally addition of 2-5 wt % of the first polymer in total polymer composition can achieve a CA value that is similar to the CA value of the pure first polymer. The results show efficient gradient behavior of the novel polymer, with the first polymer segregating sufficiently to the surface of the coated film. The thermal acid generator is activated at, for example, above 90° C., and, for example, above 120° C., and, for example above 150° C.

A film of photoresist is then coated on top of the uppermost antireflective coating and baked to substantially remove the photoresist solvent. An edge bead remover may be applied after the coating steps to clean the edges of the substrate using processes well known in the art. Photoresists can be any of the types used in the semiconductor industry, provided the photoactive compound in the photoresist and the antireflective coating absorb at the exposure wavelength used for the imaging process, such as for example 248 nm, 193 nm, 157 nm and 13.5 nm, as well as immersion and EUV radiation. Standard developers are then used to remove the undesirable areas of the photoresist. Developers that contain tetramethyl ammonium hydroxide may be used, such as AZ® 300MIF. In many cases the developer will penetrate the bottom antireflecting coating resulting in image collapse and other undesirable effects.

The optical characteristics of the antireflective coating are optimized for the exposure wavelength and other desired lithographic characteristics. As an example the absorption coefficient (k) of the novel composition for 193 nm exposure ranges from about 0.10 to about 1.00, for example from about 0.15 to about 0.75, for example from about 0.20 to about 0.40 as measured using ellipsometry. The value of the refractive index (n) ranges from about 1.25 to about 2.0, for example from about 1.60 to about 2.00.

It has surprisingly been found that, due to the presence of self-segregating first novel polymer in the antireflective composition, the developer used to develop the photoresist, is blocked from penetrating into the novel antireflective coating. The novel self-segregating polymer that segregates to the surface of the layer also significantly improves collapse margin and pattern profile without sacrificing the refractive index when high n (>1.90) low k (<0.3) is required. Pattern collapse for feature size less than 32 nm half pitch in EUV lithography is prevented. Less footing of the resist pattern is also a benefit provided by the novel first polymer in antireflective and/or underlayer compositions.

Each of the documents referred to above are incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

The refractive index (n) and the extinction coefficient (k) values of the antireflective coating in the Examples below were measured on a J. A. Woollam VASE32 ellipsometer.

The molecular weight of the polymers was measured on a Gel Permeation Chromatograph.

### Synthesis Example 1

10 g of butanetetracarboxylic acid dianhydride, 7 g of styrene glycol, 0.5 g of benzyltributylammonium chloride and 50 g of propyleneglycol monomethyletheracetate (PGMEA) were charged into a flask with a condenser, thermal controller and a mechanical stirrer. Under nitrogen and stirring, the mixture was heated to 110° C. A clear solution was obtained after ˜1-2 hr. The temperature was kept at 110° C. for another 4 hrs. Upon cooling, 45 g of PGMEA, 15.7 g of glycidyl 2,2,3,3,-tetrafluoropropyl ether and 3.5 of styrene oxide were mixed with the above solution. The reaction was kept at 125° C. for 40 hrs. After cooling down, 50 ml THF, 40 g of tetramethoxymethyl glycoluril and 0.3 g of para-toluene sulfonic acid monohydrate were added to the above reaction mixture. The mixture solution was heated and allowed to react at about 85° C. for about 3.5 hours. Upon cooling down to room temperature, the solution was dropped into a large amount of water in a high speed blender. The polymer was collected and washed thoroughly with water. Finally the polymer was dried in a vacuum oven. 45 g of polymer was obtained with a weight average molecular weight (MW) of about 14,500 g/mol.

### Synthesis Example 2

10 g of butanetetracarboxylic acid dianhydride, 7 g of styrene glycol, 0.5 g of benzyltributylammonium chloride, and 50 g of PGMEA were charged into a flask with a condenser, thermal controller and a mechanical stirrer. Under nitrogen and stirring, the mixture was heated to 110° C. A clear solution was obtained after ˜1-2 hr. The temperature was kept at 110° C. for another 4 hrs. Upon cooling, 50 g of PGMEA, 19.2 g of glycidyl 2,2,3,3,-tetrafluoroproyl ether were mixed with the above solution. The reaction was kept at 125° C. for 24 hrs. After cooling down, 50 ml THF, 40 g of tetramethoxymethyl glycoluril and 0.3 g of para-toluene sulfonic acid monohydrate were added to the above reaction mixture. The mixture solution was heated and allowed to react at about 85° C. for about 3.5 hours. Upon cooling down to room temperature, the solution was dropped into a large amount of water in a high speed blender. The polymer was collected and washed thoroughly with water. Finally the polymer was dried in a vacuum oven. 46 g of polymer was obtained with a weight average molecular weight (MW) of about 15,000 g/mol.

### Synthesis Example 3

110 g of tetramethoxymethyl glycoluril and 61 g of tris(2-hydroxyethyl)cyanuric acid were added to 350 g of dioxane. The temperature was raised to 92-94° C. and a clear solution was obtained. 0.7 g of PTSA, paratoluenesulfonic acid, was added and the reaction was allowed for 6 h at reflux. After cooling down to room temperature, 0.5 g triethyl amine was added. The solution was precipitated in n-butyl acetate at 5° C. The polymer was filtered and dried under vacuo. The polymer obtained had a weight average molecular weight of about 2200 g/mol.

### Synthesis Example 4

23 g of bis(2-carboxyethyl)isocyanurate and 16 g of anhydrous ethylene glycol were placed in a 500 ml flask. 150 g of 4M HCl dioxane solution was added under N₂. The mixture was stirred and temperature was gradually raised in 50, 60, 70, 80° C. increments over the course of about 1 hour. The reaction was refluxed for 24 hours at 96-97° C. The reaction solution was cooled to room temperature and filtered. Solvent was removed by rotary evaporation to dryness. The product was obtained by recrystallization in THF/isobutyl acetate. The solid was collected by filtration. After drying under vacuo at ˜40° C., 12 g of white powdery product was obtained.

### Synthesis Example 5

30 grams of tetramethoxymethyl glycoluril, 10.4 grams of 3-iodophenol, 40 ml of THF and 40 ml of PGMEA were charged into a flask with a thermometer, mechanical stirrer and a cold water condenser. After a catalytic amount of paratoluenesulfonic acid monohydrate (0.3 g) was added, the reaction was maintained at 80° C. for about 7 hrs. The reaction solution was then cooled to room temperature and filtered. The filtrate was slowly poured into distilled water while stirring to precipitate the polymer. The polymer was collected by filtration. After drying, the polymer was re-dissolved in THF and precipitated in water. The polymer was filtered, washed thoroughly with water and dried in a vacuum oven. 24.0 g of polymer product was obtained with a weight average molecular weight of about 3,500 g/mol. Iodine in the polymer was 21.7% as determined by elemental analysis.

### Synthesis Example 6

10 g of butanetetracarboxylic acid dianhydride, 7 g of styrene glycol, 0.5 g of benzyltributylammonium chloride, and 35 g of PGMEA were charged into a flask with a condenser, thermal controller and a mechanical stirrer. Under nitrogen and stirring, the mixture was heated to 110° C. A clear solution was obtained after ˜1-2 hours. The temperature was kept at 110° C. for 3 hours. Upon cooling, 60 g of PGMEA and 36 g of propylene oxide were mixed with the above solution. The reaction was kept at 50° C. for 48 hrs. The reaction solution was cooled to room temperature and slowly poured into a large amount of water in a high-speed blender. The polymer was collected and washed thoroughly with water. Finally, the polymer was dried in a vacuum oven. 16 g of polymer was obtained with an average molecular weight (MW) of about 20,000 g/mol.

### Composition and Coating Example 1

1 g of the polymer from Synthesis Example 1 was dissolved in 30 g of PGMEA/propylene glycol monomethyl ether (PGME)/gamma valerolactone (GVL) 68/29/3 solvent to make a 3.3 wt % solution. A mixture of 0.03 g of 10% of dodecylbenzene sulfonic acid triethylamine salt in PGMEA/PGME 70/30, 0.03 g of 10% of nonafluorobutanesulfonic acid triethylamine salt in PGMEA/PGME 70/30 and 0.06 g of 10% of p-toluene sulfonic acid triethylamine salt in PGMEA/PGME 70/30 was added in the polymer solution. The mixture was filtered through a micro filter with a pore size of 0.2 um. The solution was spin coated on a silicon wafer for 40 seconds at 1500 rpms. The coated wafer was then heated on a hot plate for 1 minute at 205° C. The anti-reflective coating was analyzed on a spectroscopic ellipsometer. The optimized refractive index “n” at 193 nm was 1.84 and the absorption coefficient “k” was 0.35.

### Composition and Coating Example 2

The Composition and Coating Example 1 was repeated replacing Synthesis Example 1 with Synthesis Example 2. The resultant anti-reflective coating was analyzed on a spectroscopic ellipsometer. The optimized refractive index “n” at 193 nm was 1.80 and the absorption coefficient “k” was 0.25.

### Composition and Coating Example 3

The Composition and Coating Example 1 was repeated replacing Synthesis Example 1 with 0.7 g of the polymer from Synthesis Example 3 and 0.3 g of the product from Synthesis Example 4. The resultant anti-reflective coating was analyzed on a spectroscopic ellipsometer. The optimized refractive index “n” at 193 nm was 1.97 and the absorption coefficient “k” was 0.27.

### Composition and Coating Example 4

0.5 g of the solution from Composition 1 and 9.5 g of the solution from Composition 3 were mixed well on a roller. The mixture was filtered through a micro filter with a pore size of 0.2 um. The solution was spin coated on a silicon wafer for 40 seconds at 1500 rpms. The coated wafer was then heated on a hot plate for 1 minute at 205° C. The anti-reflective coating was analyzed on a spectroscopic ellipsometer. The “apparent” optimized refractive index “n” at 193 nm was 1.953 and the absorption coefficient “k” was 0.26.

### Composition and Coating Example 5

The Composition and Coating Example 4 was repeated replacing 0.5 g of the solution from Composition 1 and 9.5 g of the solution from Composition 3 with 1 g of the solution from Composition 1 and 9 g of the solution from Composition 3. The resultant anti-reflective coating was analyzed on a spectroscopic ellipsometer. The “apparent” optimized refractive index “n” at 193 nm was 1.944 and the absorption coefficient “k” was 0.26.

### Composition and Coating Example 6

The Composition and Coating Example 4 was repeated replacing 0.5 g of the solution from Composition 1 and 9.5 g of the solution from Composition 3 with 2 g of the solution from Composition 1 and 8 g of the solution from Composition 3. The resultant anti-reflective coating was analyzed on a spectroscopic ellipsometer.

### Composition and Coating Example 7

5 g of the solution from Composition 1 and 5 g of the solution from Composition 3 were mixed well on a roller. The mixture was filtered through a micro filter with a pore size of 0.2 micron. The solution was spin coated on a silicon wafer for 40 seconds. The coated wafer was then heated on a hot plate for 1 minute at 205° C. The resultant anti-reflective coating was analyzed on a spectroscopic ellipsometer.

### Composition and Coating Example 8

0.6 g of the polymer from Synthesis Example 3 and 0.4 g of the product from Synthesis Example 4 were dissolved in 29.5 g of PGMEA/PGME/GVL 68/29/3 solvent to make a 3.3 wt % solution. A mixture of 0.03 g of 10% of dodecylbenzene sulfonic acid triethylamine salt in PGMEA/PGME 70/30, 0.03 g of 10% of nonafluorobutanesulfonic acid triethylamine salt in PGMEA/PGME 70/30 and 0.06 g of 10% of p-toluene sulfonic acid triethylamine salt in PGMEA/PGME 70/30 was added in the polymer solution. 0.5 g of 10% solution of polymer from Synthesis Example 1 was added in above formulation. The mixture was filtered through a micro filter with a pore size of 0.2 micron. The solution was spin coated on a silicon wafer for 40 seconds at 1500 rpms. The coated wafer was then heated on a hot plate for 1 minute at 205° C. The anti-reflective coating was analyzed on a spectroscopic ellipsometer. The optimized refractive index “n” at 193 nm was 1.96 and the absorption coefficient “k” was 0.26.

### Composition and Coating Example 9

The Composition and Coating Example 8 was repeated replacing 0.5 g of a 10% solution of Synthesis Example 1 with 1 g of 10% solution of polymer from Synthesis Example 1 was added in above formulation. The resultant anti-reflective coating was analyzed on a spectroscopic ellipsometer. The optimized refractive index “n” at 193 nm was 1.95 and the absorption coefficient “k” was 0.26.

### Composition and Coating Example 10

The Composition and Coating Example 8 was repeated replacing 0.5 g of a 10% solution of the polymer from Synthesis Example 1 with 0.5 g of a 10% solution of the polymer from Synthesis Example 2. The resultant anti-reflective coating was analyzed on a spectroscopic ellipsometer. The optimized refractive index “n” at 193 nm was 1.96 and the absorption parameter “k” was 0.25.

### Composition and Coating Example 11

0.7 g of the polymer from Synthesis Example 3, 0.1 g of the product from Synthesis Example 6, and 0.2 g of the product from Synthesis Example 4 were dissolved in 29.5 g of PGMEA/PGME/GVL 68/29/3 solvent to make a 3.3 wt % solution. A mixture of 0.03 g of 10% of dodecylbenzene sulfonic acid triethylamine salt in PGMEA/PGME 70/30, 0.03 g of 10% of nonafluorobutanesulfonic acid triethylamine salt in PGMEA/PGME 70/30 and 0.06 g of 10% of p-toluene sulfonic acid triethylamine salt in PGMEA/PGME 70/30 was added in the polymer solution. 1 g of 1% solution of polymer from Synthesis Example 1 was added in above formulation. The mixture was filtered through a micro filter with a pore size of 0.2 um. The solution was spin coated on a silicon wafer for 40 seconds at 1500 rpms. The coated wafer was then heated on a hot plate for 1 minute at 205° C. The resulting anti-reflective coating was analyzed on a spectroscopic ellipsometer. The optimized refractive index “n” at 193 nm was 1.90 and the absorption coefficient “k” was 0.25.

### Composition and Coating Example 12

The Composition and Coating Example 11 was repeated replacing 0.7 g of the polymer from Synthesis Example 3, 0.1 g of the product from Synthesis Example 6, and 0.2 g of the product from Synthesis Example 4 with 0.58 g of the polymer from Synthesis Example 3, 0.25 g of the product from Synthesis Example 6, and 0.17 g of the product from Synthesis Example 5. The resulting anti-reflective coating was analyzed on a spectroscopic ellipsometer. The optimized refractive index “n” at 193 nm was 1.73 and the absorption coefficient “k” was 0.28.

Contact Angle Measurements

BARC film surfaces resulted from Composition and Coating Examples 1-7 were subjected to contact angle studies. For each coated wafer, five drops of water were added to the center, up, down, left and right areas of wafer. Contact Angle (CA) of water was measured by using VCA 2500XE system. Averaging these five contact angle data gives BARC's contact angle to water. The results from Composition and Coating Examples 1, 3-7 are listed in Table 1. CA of BARC film has increased significantly by adding 1% of hydrophobic polymer or more from Synthesis Example 1 or Synthesis Example 2 in the high n formulation (Composition and Coating Example 3). CA of Composition Example 2 was measured to be 77°. The slightly higher CA of Composition Example 2 is due to higher fluoro content in polymer from Synthesis Example 2 than that in polymer from Synthesis Example 1.

TABLE 3
CA measurements for formulation Example 3-7 and 1

| | |
|---|---|
| Composition (wt %) | Contact |

| Formulation | Formulation | Formulation | angle to |
|---|---|---|---|
| Example | example 1 | example 3 | water |
| 3 | 0 | 100 | 46.1 |
| 4 | 5 | 95 | 72.4 |
| 5 | 10 | 90 | 73.2 |
| 6 | 20 | 80 | 73.4 |
| 7 | 50 | 50 | 74.0 |
| 1 | 100 | 0 | 74.4 |

### Comparative Lithography Performances Example 1

The performance of the anti-reflective coating formulation from Composition and Coating Example 3 was evaluated using AZ® 2110P photoresist (product of AZ Electronic Materials USA Corp., Somerville, N.J.). A silicon wafer was coated with AZ® EB18B bottom antireflective coating composition (AZ Electronic Materials USA Corp., Somerville, N.J.) and baked at 220° C. for 60 seconds to form a 50 nm thick film. Then a 25 nm thick film of Composition and Coating Example 3 was coated over and baked at 205° C. for 60 seconds. Using AZ® EXP AX1120P photoresist, a 190 nm film was coated and baked at 100° C. for 60 seconds. The wafer was then imagewise exposed using a 193 nm exposure tool. The exposed wafer was baked at 110° C. for 60 seconds and developed using AZ® 300MIF developer for a prolonged 120 seconds. The top down patterns when observed under scanning electron microscope showed collapse caused by developer penetration during long period of immersion in developer.

### Lithography Performances Example 1

The performance of the anti-reflective coating formulation from Composition and Coating Example 4 was evaluated using AZ® 2110P photoresist (product of AZ Electronic Materials USA Corp., Somerville, N.J.). A silicon wafer was coated with AZ® EB18B bottom antireflective coating composition (AZ Electronic Materials USA Corp., Somerville, N.J.) and baked at 220° C. for 60 seconds to form a 50 nm thick film. Then a 25 nm thick film of Formulation and Coating Example 4 was coated over and baked at 205° C. for 60 seconds. Using AZ® EXP AX1120P photoresist a 190 nm film was coated and baked at 100° C. for 60 seconds. The wafer was then imagewise exposed using a 193 nm exposure tool. The exposed wafer was baked at 110° C. for 60 seconds and developed using AZ® 300MIF developer for a prolonged 120 seconds. The top down and cross-section patterns when observed under scanning electron microscope showed no significant collapse in the process window. The pattern profile has shown reduced footing/scum comparing to the results from Comparative Lithography Performances Example 1.

### Lithography Performances Example 2

The performance of the anti-reflective coating formulation from Formulation and Coating Example 8 was evaluated using AZ® 2110P photoresist (product of AZ Electronic Materials USA Corp., Somerville, N.J.). A silicon wafer was coated with AZ® EB18B bottom antireflective coating composition (AZ Electronic Materials USA Corp., Somerville, N.J.) and baked at 220° C. for 60 seconds to form a 50 nm thick film. Then a 25 nm thick film of Formulation and Coating Example 8 was coated over and baked at 205° C. for 60 seconds. Using AZ® EXP AX1120P photoresist a 190 nm film was coated and baked at 100° C. for 60 seconds. The wafer was then imagewise exposed using a 193 nm exposure tool. The exposed wafer was baked at 110° C. for 60 seconds and developed using AZ® 300MIF developer for a prolonged 120 seconds. The top down and cross-section patterns when observed under scanning electron microscope showed no significant collapse in the process window. The pattern profile has shown reduced footing/scum comparing to the results from Comparative Lithography Performances Example 1.

### Lithography Performances Example 3

The performance of the anti-reflective coating formulation from Formulation and Coating Example 11 was evaluated using AZ® 2110P photoresist (product of AZ Electronic Materials USA Corp., Somerville, N.J.). A silicon wafer was coated with AZ® EB18B bottom antireflective coating composition (AZ Electronic Materials USA Corp., Somerville, N.J.) and baked at 220° C. for 60 seconds to form a 50 nm thick film. Then a 26 nm thick film of Formulation and Coating Example 11 was coated over and baked at 205° C. for 60 seconds. Using AZ® EXP AX1120P photoresist a 190 nm film was coated and baked at 100° C. for 60 seconds. The wafer was then imagewise exposed using a 193 nm exposure tool. The exposed wafer was baked at 110° C. for 60 seconds and developed using AZ® 300MIF developer for a prolonged 120 seconds. The top down and cross-section patterns when observed under scanning electron microscope showed no significant collapse in the process window. The pattern profile has shown reduced footing/scum comparing to the results from Comparative Lithography Performances Example 1.

### Lithography Performances Example 4

The diluted solution of Formulation and Coating Example 12 was filtered using a 0.2 um nylon syringe filter. The sample was then coated on a 8″ silicon wafers on a Tel Act12 track, with a post application bake of 200° C./60 seconds. EUV SEVR-139 photoresist available from SEMATECH was coated on top of underlayer. It was baked and exposed at SEMATECH using their 0.3NA (numerical aperture) Albany Eximer micro-exposure tool (eMET). After development, the lithographic performance was evaluated with both CDSEM topdown measurements and cross section pictures taken under an SEM microscope. The 30 nm HP showed good resist pattern profiles with minimal footing and clean lines without scumming. The EUV lithography was shown to have excellent photosensitivity of 30 nm 1:1 L/S at 11.7 mJ/cm2. The pattern also had good collapse margin, depth of focus and process window.

As can be seen from the above examples and discussion, unexpected results were obtained that allowed improvements in lithographic properties. The examples presented are meant to illustrate the disclosure and are not to be construed and limited to those materials presented. For example, many bottom antireflective compositions can benefit from addition of the disclosed polymers.

We claim:

1. An antireflective coating composition for a photoresist layer comprising a first polymer and an acid generator, where the first polymer comprises at least one unit of structure 1, 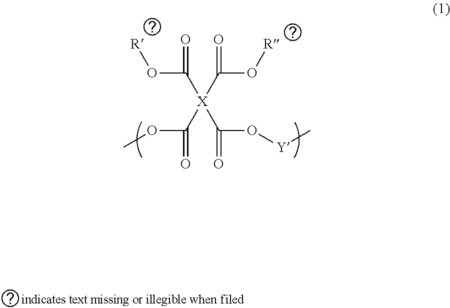
wherein, X is a linking moiety selected from a nonaromatic linking group selected from C₁-C₂₀ substituted or unsubstituted aliphatic, heteroaliphatic, cycloaliphatic or heterocycloaliphatic linking groups, an aromatic linking group and mixtures thereof, wherein R′ is a group of structure (2), or (3) or a mixture thereof, 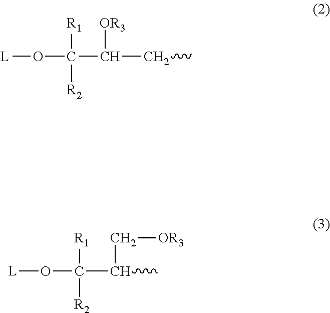
wherein R₁ and R₂ are independently selected from H and C₁-C₄ alkyl, R₃ is ˜˜˜CH₂—Z, wherein Z is an acid crosslinkable aminoplast and L is a C₁-C₂₀ substituted or unsubstituted, branched or unbranched aliphatic, substituted or unsubstituted, branched or unbranched aromatic, or substituted or unsubstituted, branched or unbranched aralkyl group which is fully or partially substituted with fluorine, R″ is selected from a group consisting of C₁-C₂₀ substituted or unsubstituted, branched or unbranched aliphatic, C₁-C₂₀ substituted or unsubstituted, branched or unbranched aromatic, C₁-C₂₀ substituted or unsubstituted, branched or unbranched aralkyl group, structure (2) and structure (3), where R₃ is selected from a group consisting of H, C₁-C₂₀ substituted or unsubstituted, branched or unbranched aliphatic, substituted or unsubstituted, branched or unbranched aromatic, substituted or unsubstituted, branched or unbranched alkylene aryl, substituted or unsubstituted, branched or unbranched aralkyl group, ˜˜˜CH₂—Z, wherein Z is an acid crosslinkable aminoplast, and mixtures thereof, and Y′ is independently a (C₁-C₂₀) substituted or unsubstituted, branched or unbranched aliphatic, substituted or unsubstituted, branched or unbranched aromatic, or substituted or unsubstituted, branched or unbranched aralkyl linking groups.

2. The coating composition of claim 1, further comprising a second polymer comprising a structural unit derived from an aminoplast and a structural unit derived from a diol, triol, dithiol, trithiol, polyols, diacid, triacid, polyacids, diimide, diamide, imide-amide, or mixture thereof, where the diol, dithiol, triol, trithiol, diacid, triacid, diimide, diamide, or imide-amide optionally containing one or more nitrogen and/or sulfur atoms or containing one or more alkene groups, or hydroxy group containing polymers, wherein the second polymer is present in the composition greater than about 2 wt %.

3. The coating composition of claim 2, further comprising a second polymer free of fluorination.

4. The coating composition of claim 2, wherein the aminoplasts are selected from monomeric or oligomeric melamines, guanamines, methylols, monomeric or oligomeric glycolurils, N-substituted cyanuric acids, triazines, hydroxy alkyl amides, epoxy and epoxy amine resins, blocked isocyanates, and divinyl monomers.

5. The coating composition of claim 2, wherein the acid generator is a thermal acid generator selected from alkyl ammonium salts of organic acids, ammonium salts of organic sulfonic acids, phenolic sulfonate esters, nitrobenzyl tosylates, and metal-free iodonium and sulfonium salts

6. The coating composition of claim 2, wherein the first polymer is capable of segregating from any other materials present toward the surface of the coating when coated and substantially dried.

7. The coating composition of claim 1, wherein the first polymer is of structure 4, 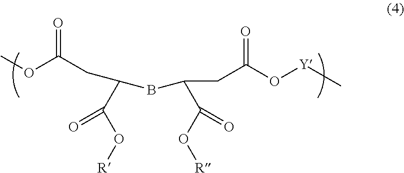
wherein, B is a single bond or C₁-C₆ nonaromatic aliphatic group, R′ is the group structure (2), or (3) wherein R₁ and R₂ are independently selected from H and C₁-C₄ alkyl, R₃ is ˜˜˜CH₂—Z, wherein Z is an acid crosslinkable aminoplast and L is a C₁-C₂₀ substituted or unsubstituted, branched or unbranched aliphatic, aromatic, or aralkyl linking group which is fully or partially substituted with fluorine groups, R″ is selected from a group consisting of C₁-C₂₀ substituted or unsubstituted, branched or unbranched aliphatic, C₁-C₂₀ substituted or unsubstituted, branched or unbranched aromatic, C₁-C₂₀ substituted or unsubstituted, branched or unbranched aralkyl group, structure (2) and structure (3), where R₃ is selected from a group consisting of H, C₁-C₂₀ substituted or unsubstituted, branched or unbranched aliphatic, substituted or unsubstituted, branched or unbranched aromatic, substituted or unsubstituted, branched or unbranched alkylene aryl, substituted or unsubstituted, branched or unbranched aralkyl group, and ˜˜˜CH₂—Z, wherein Z is an acid crosslinkable aminoplast, and mixtures thereof, and Y′ is a (C₁-C₂₀) substituted or unsubstituted, branched or unbranched aliphatic, (C₁-C₂₀) substituted or unsubstituted, branched or unbranched aromatic, or (C₁-C₂₀) substituted or unsubstituted, branched or unbranched aralkyl linking group.

8. The coating composition of claim 6, wherein the polymer is capable of segregating from any other materials present toward the surface of the coating when coated and substantially dried.

9. The coating composition of claim 6, further comprising a second polymer free of fluorination.

10. A polymer comprising at least one unit of structure 1, 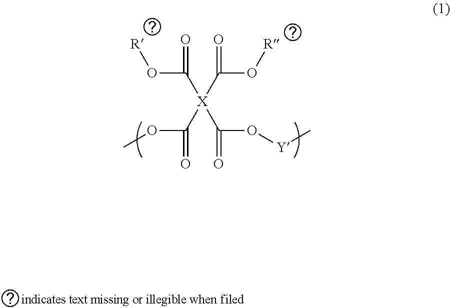
wherein, X is a linking moiety selected from a nonaromatic linking group selected from C₁-C₂₀ substituted or unsubstituted aliphatic, heteroaliphatic, cycloaliphatic or heterocycloaliphatic linking groups, an aromatic linking group and mixtures thereof, wherein R′ is a group of structure (2), or (3) or a mixture thereof, 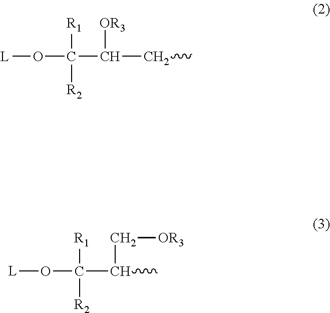
wherein R₁ and R₂ are independently selected from H and C₁-C₄ alkyl, R₃ is ˜˜˜CH₂—Z, wherein Z is an acid crosslinkable aminoplast and L is a C₁-C₂₀ substituted or unsubstituted, branched or unbranched aliphatic, substituted or unsubstituted, branched or unbranched aromatic, or substituted or unsubstituted, branched or unbranched aralkyl group which is fully or partially substituted with fluorine, R″ is structure (2) or (3) where R₃ is selected from a group consisting of C₁-C₂₀ substituted or unsubstituted, branched or unbranched aliphatic, aromatic, or aralkyl linking group, structure (2) and (3) where R₃ is selected from a group consisting of H, C₁-C₂₀ substituted or unsubstituted, branched or unbranched aliphatic, substituted or unsubstituted, branched or unbranched aromatic, substituted or unsubstituted, branched or unbranched alkylene aryl, substituted or unsubstituted, branched or unbranched aralkyl group, ˜˜˜CH₂—Z, wherein Z is an acid crosslinkable aminoplast, and mixtures thereof, and Y′ is independently a (C₁-C₂₀) substituted or unsubstituted, branched or unbranched aliphatic, substituted or unsubstituted, branched or unbranched aromatic, or substituted or unsubstituted, branched or unbranched aralkyl linking group.

11. The polymer of claim 10, wherein the acid crosslinkable aminoplasts are selected from monomeric or oligomeric melamines, guanamines, methylols, monomeric or oligomeric glycolurils, N-substituted cyanuric acids, triazines, hydroxy alkyl amides, epoxy and epoxy amine resins, blocked isocyanates, and divinyl monomers.

12. The polymer of claim 10, wherein the polymer is of structure 4, 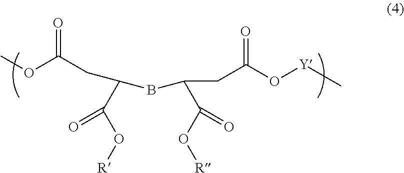
wherein, B is a single bond or C₁-C₆ nonaromatic aliphatic group, R′ is the group structure (2), or (3) wherein R₁ and R₂ are independently selected from H and C₁-C4 alkyl, R₃ is ˜˜˜CH₂—Z, wherein Z is an acid crosslinkable aminoplast and L is a C₁-C₂₀ substituted or unsubstituted, branched or unbranched aliphatic, aromatic, or aralkyl linking group which is fully or partially substituted with fluorine groups, R″ is structure (2) or (3) or a mixture with where R₃ is selected from a group consisting of H, C₁-C₂₀ substituted or unsubstituted, branched or unbranched aliphatic, aromatic, or aralkyl linking group, and ˜˜˜CH₂—Z, wherein Z is an acid crosslinkable aminoplast and Y′ is independently a (C₁-C₂₀) substituted or unsubstituted, branched or unbranched aliphatic, aromatic, or aralkyl linking group.

13. The polymer of claim 12, wherein the acid crosslinkable aminoplasts are selected from monomeric or oligomeric melamines, guanamines, methylols, monomeric or oligomeric glycolurils, hydroxy alkyl amides, epoxy and epoxy amine resins, blocked isocyanates, and divinyl monomers.

14. A process for forming an image comprising,
a) coating and baking a substrate with the antireflective coating composition of claim 2;
b) coating and drying a photoresist film on top of the antireflective coating;
c) imagewise exposing the photoresist;
d) developing an image in the photoresist; and
e) optionally baking the substrate after the exposing step.

15. The process of claim 14, where the photoresist is imagewise exposed at wavelengths between 13 nm to 250 nm.

16. The process of claim 14, where the photoresist comprises a polymer and a photoactive compound.

17. The process of claim 14, where the antireflective coating is baked at temperatures greater than 90° C.

18. An article comprising a substrate with a layer of antireflective coating composition of claim 2 and thereon a coating of photoresist comprising a polymer and a photoactive compound.
